(19) United States
(12) Patent Application Publication
(10) Pub. No.: US 2008/0215955 A1
(43) Pub. Date: Sep. 4, 2008

(54) SEMICONDUCTOR STORAGE DEVICE

(75) Inventors: Daijiro Kimbara, Kanagawa (JP); Hiroo Nakano, Kanagawa (JP); Tetsuro Iwamura, Kanagawa (JP); Atsushi Kobayashi, Kanagawa (JP); Masahiko Motoyama, Kanagawa (JP); Hideki Teraoka, Fukuoka (JP); Atsushi Shimbo, Tokyo (JP); Hideo Shimizu, Kanagawa (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/032,872

(22) Filed: Feb. 18, 2008

(30) Foreign Application Priority Data
Feb. 19, 2007 (JP) 2007-038293

(51) Int. Cl. G11C 29/00; G06F 11/00

(52) U.S. Cl. 714/768; 714/E11.002

(57) ABSTRACT

A semiconductor storage device includes: a memory configured to store data at a first address and store an error detecting code corresponding to the data at a second address which is set up in a predetermined relation with the first address and different from the first address; and an address storage portion configured to store information on address relation between the first address and the second address.

### CROSS REFERENCE TO RELATED APPLICATION

This application is based upon and claims the benefit of priority from the prior Japanese Patent Application No. 2007-038293 filed on Feb. 19, 2007; the entire contents of which are incorporated herein by this reference.

### BACKGROUND OF THE INVENTION

1. Field of the Invention

The present invention relates to a semiconductor storage device including a memory configured to store data to be protected.

2. Description of the Related Art

Following diffusion of the Internet, deals on a network from mobile terminal devices such as personal computers and cell-phones are increasing, and it is required to secure safe communication by means of cryptographic technology. In particular, attention is focused on an IC card which is more difficult to counterfeit and has higher security than a magnetic card.

As for the IC card, however, various attack techniques are announced against cryptographic implementation, and so countermeasures against the attack techniques are essential.

Failure-based analysis can be named as one of the methods of attacking the IC card. This method purposely changes a bit pattern of data inside the IC card by physical means from outside the IC card during calculation of cryptography and generates an error in a calculation result so as to analyze a cryptographic key which is confidential information.

As for an example of the attack by the failure-based analysis, the attack technique against an RSA decoding scheme using Chinese remainder theorem (hereinafter referred to as CRT) is known, which has been announced by Boneh et al. (refer to D. Boneh, R. A. DeMillo and R. J. Lipton, “On the Importance of Checking Computations” Submitted to Eurocrypt '97 for instance).

Of the attack techniques against the RSA decoding scheme using the CRT, a technique of tampering with memory contents is known. There is a method of detecting that the memory contents have been tampered with, which utilizes an error detecting code (EDC) (refer to Japanese Patent Laid-Open No. 2003-51817 for instance).

The method renders tampering with a data portion of a memory detectable by an error detection circuit.

However, the attack made by an attacker for the sake of attempting the failure-based analysis is not limited to directly tampering with the data portion of the memory. There is also a method, for instance, of attacking an address decoder, changing a memory address and causing a memory address different from a correct memory address to be accessed and thereby causing a system of a memory card IC to read out improper data which is not expected by the system.

As for the attack method of attacking the address decoder, reading out the improper data and putting the IC in a failed state, there is a problem that the attack is not detectable by the method of Japanese Patent Laid-Open No. 2003-51817.

Therefore, it is desirable that the error is detectable even when the system thus reads the unexpected improper data.

### SUMMARY OF THE INVENTION

A semiconductor storage device according to an aspect of the present invention includes: a memory configured to store data at a first address and store an error detecting code corresponding to the data at a second address which is set up in a predetermined relation with the first address and different from the first address; and address storage unit configured to store information on address relation between the first address and the second address.

A semiconductor storage device according to an aspect of the present invention includes: a memory configured to store combination data having mutually different first data and second data divided at a first address and store an error detecting code corresponding to the first or second data at a second address which is set up in a predetermined relation with the first address and different from the first address; and an address storage portion configured to store information on address relation between the first address and the second address.

A semiconductor storage device according to an aspect of the present invention includes: a first memory configured to store data at a first address; a second memory configured to store an error detecting code corresponding to the data at a second address which is set up in a predetermined relation with the first address and different from the first address; and an address storage portion configured to store information on address relation between the first address and the second address.

### BRIEF DESCRIPTION OF THE DRAWINGS

FIG. 1 is a schematic diagram showing a configuration of an IC card chip in which a semiconductor storage device according to an embodiment of the present invention is incorporated;

FIG. 2 is a diagram showing an external view of an IC card body on which the IC card chip of FIG. 1 is mounted;

FIG. 3 is a diagram showing a schematic configuration of the semiconductor storage device according to an embodiment of the present invention in a state of operational description on data readout;

FIG. 4 is a diagram showing a schematic configuration of the semiconductor storage device according to an embodiment of the present invention in a state of operational description on error detecting code readout;

FIG. 5 is a flowchart showing operational contents on performing data readout and data verification from the semiconductor storage device according to an embodiment of the present invention;

FIG. 6 is an explanatory diagram of operation of first data readout when an address decoder is attacked by an attacker;

FIG. 7 is an explanatory diagram of operation of second error detecting code readout and the data verification when the address decoder is attacked by the attacker;

FIG. 8 is a diagram showing a first storage form example which stores the data and error detecting code at different memory addresses;

FIG. 9 is a diagram showing a second storage form example which stores the data and error detecting code at different memory addresses;

FIG. 10 is a diagram showing a third storage form example which stores the data and error detecting code at different memory addresses;

FIG. 11 is a diagram showing a fourth storage form example which stores the data and error detecting code at different memory addresses;

FIG. 12 is an explanatory diagram of operation of a fifth storage form example which stores a part of the data and the error detecting code at different memory addresses and the first data readout;

FIG. 13 is an explanatory diagram of operation of the second readout and data verification in FIG. 12;

FIG. 14 is an explanatory diagram of operation of a sixth storage form example which stores the data and the error detecting code at a different memory address and the first data readout;

FIG. 15 is an explanatory diagram of operation of the second error detecting code readout and the data verification in FIG. 14;

FIG. 16 is a diagram showing a configuration of a comparison example in which the data and the error detecting code are stored at the same memory address;

FIG. 17 is an explanatory diagram of operation in the case where an attack is made by tampering with a bit pattern of the data in the case of the configuration of FIG. 16; and

FIG. 18 is an explanatory diagram of operation in the case where an attack is made by tampering with the memory address in the case of the configuration of FIG. 16.

### DETAILED DESCRIPTION OF THE PREFERRED EMBODIMENTS

Hereafter, embodiments of the present invention will be described with reference to the drawings.

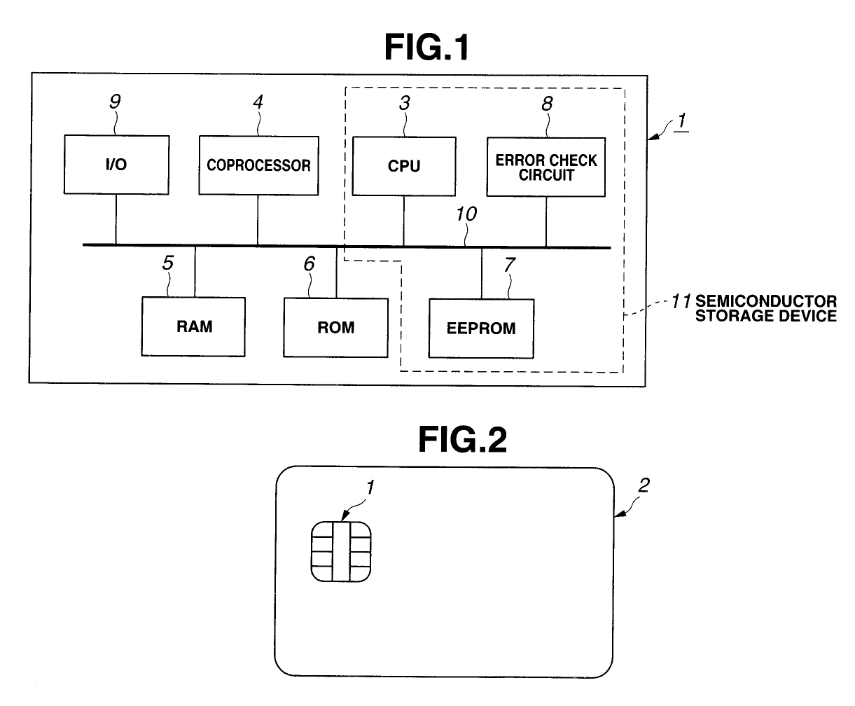

FIG. 1 shows a configuration of an IC card chip 1 in which a semiconductor storage device according to an embodiment of the present invention is included. As shown in FIG. 2, the IC card chip 1 can be mounted on an IC card body 2 which is in a business card size for instance.

The IC card chip 1 shown in FIG. 1 is connected with a CPU 3 configured to control the entire operation of the IC card chip 1, a coprocessor 4, an RAM 5, an ROM 6, an EEPROM 7, an error check circuit 8 and an input-output portion (I/O) 9 via a bus 10 respectively.

The coprocessor 4 has an ancillary function of the CPU 3, and performs arithmetic processing of a large calculation amount such as modular exponentiation division of RSA. The RAM 5 is used as a work area for the CPU 3 to perform processing such as readout and writing, and is also used, for instance, to hold information on a halfway result of cryptographic processing. The ROM 6 is a memory readable from the CPU 3, and has programs for operational control of the CPU 3 such as a cryptographic processing program stored therein.

The EEPROM 7 is a nonvolatile and electrically rewritable memory capable of readout and writing from the CPU 3. The EEPROM 7 has confidential data such as a secret key used when the cryptographic processing stored (held) therein is performed together with an error detecting code corresponding to the data so as to be at different memory addresses.

The following will describe the data and the error detecting code corresponding to the data by taking the case of the EEPROM 7 as a common memory. Without such limitation, however, the data and the error detecting code may also be stored in separate memories. For instance, it is also possible to prepare a first memory and a second memory which are physically separate and store the data in a memory cell of the first memory and store the corresponding error detecting code in a memory cell of the second memory.

To be able to handle the first memory and the second memory which are separate as one memory, the memory cell of the first memory and the memory cell of the second memory may be managed as memory cells of a comprehensive memory at a common memory address. In this case, the data and the corresponding error detecting code are also stored in the memory cells of different memory addresses.

The error check circuit 8 is a circuit configured to check whether or not there is an error of the data read out from the memory to be protected, such as the EEPROM 7. And the data and the error detecting code read out from the memory are captured by the error check circuit 8 first. As a result of verification (checking) whether the data matches the error detecting code corresponding to the data, the data is transmitted to the CPU 3 or the coprocessor 4 via the bus 10 if no error has occurred.

In the case where an error has occurred as a result of the verification, an error detecting signal is outputted. And in this case, the CPU 3 and the like do not allow the cryptographic processing and the like to be performed so as to secure protection of the data or confidentiality of the data.

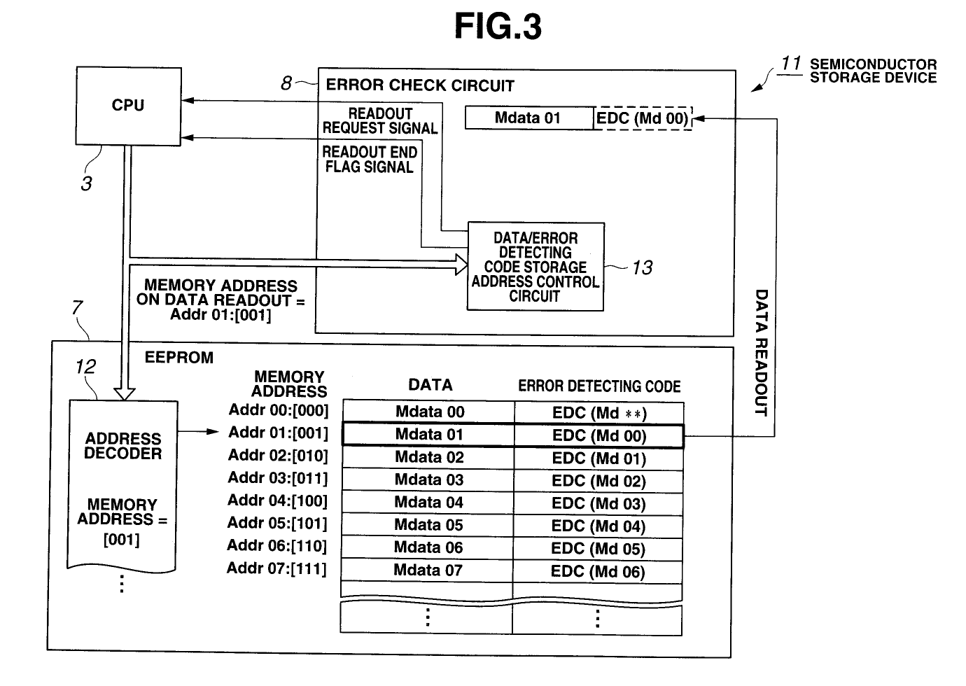

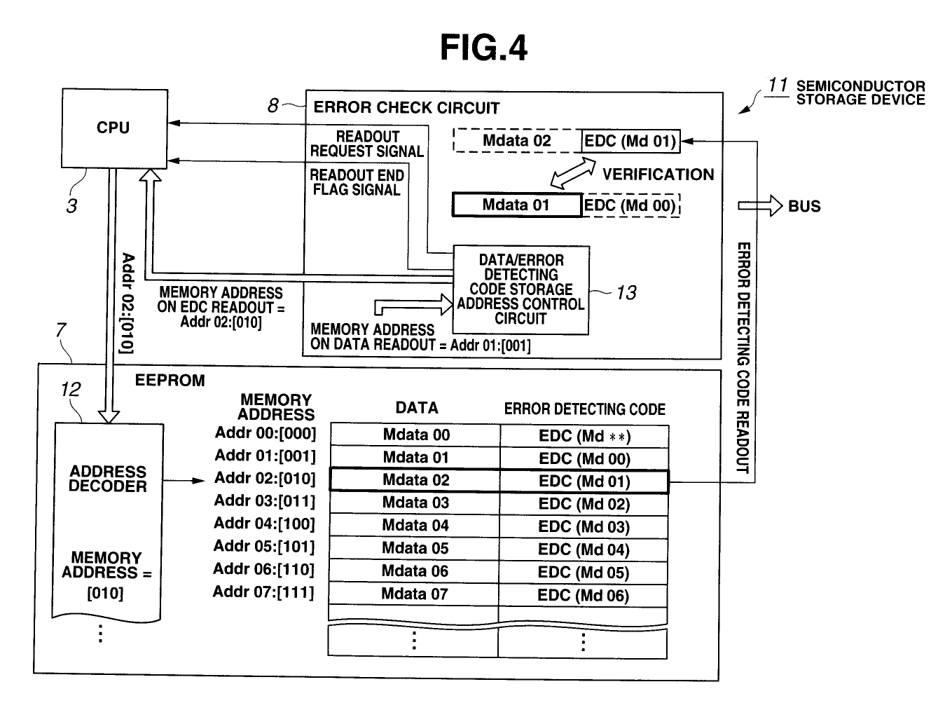

FIGS. 3 and 4 show the configuration of a semiconductor storage device 11 according to the present embodiment in a state of operation of data readout and error detecting code readout.

FIGS. 3 and 4 show the semiconductor storage device 11 in the configuration including the CPU 3, the EEPROM 7 as a memory configured to store data to be protected and the error check circuit 8. The semiconductor storage device 11 may also have the configuration including the coprocessor 4 as well as the CPU 3. The semiconductor storage device 11 includes at least a memory (EEPROM 7 in this case).

The following will describe the case of the EEPROM 7 as the memory. However, the following may also be applied to the ROM 6 and the RAM 5.

As shown in FIGS. 3 and 4, the EEPROM 7 has the data to be protected and the error detecting code of the data stored and held at different memory addresses. And the CPU 3 can read out the data and the error detecting code corresponding to the data held in the EEPROM 7 via an address decoder 12 in the EEPROM 7.

In this case, the data and the error detecting code corresponding to the data are stored at different memory addresses. Therefore, the CPU 3 performs a readout process to the EEPROM 7 multiple times in order to read out the data and the error detecting code corresponding to the data.

The error check circuit 8 has an error check function for checking whether or not there is an error in the data read out by verifying the data with the error detecting code corresponding to the data.

The error check circuit 8 further includes a data/error detecting code storage address control circuit 13 as an address storage unit configured to store memory address-related information as a pair of the memory address of each individual data stored in the EEPROM 7 and the memory address at which the error detecting code corresponding to the data is stored.

According to the present embodiment, the data/error detecting code storage address control circuit 13 is provided within the error check circuit 8. Without such limitation, however, the data/error detecting code storage address control circuit 13 may also be provided outside the error check circuit 8.

And in the case of storing the data and the error detecting code corresponding to the data in the EEPROM 7, they are stored at different memory addresses according to the memory address-related information stored in the data/error detecting code storage address control circuit 13 respectively.

As a matter of course, it is also possible to store the data and the corresponding error detecting code at different memory addresses and then create the information indicating the memory address relation thereof.

In the example shown in FIG. 3, the memory address at which the corresponding error detecting code is stored is a different memory address shifted by one memory address against the memory address at which the data is stored.

For instance, if a memory address Addr at which data Mdataij is stored is ij (in the decimal system), a memory address Addr at which a corresponding error detecting code EDC (Mdij) is stored is ij+1.

The information on the memory addresses in the relation is stored in the data/error detecting code storage address control circuit 13. In the following, the memory address ij is indicated as Addrij, and the corresponding error detecting code of the data Mdataij is indicated as EDC (Mdij).

According to the present embodiment, the memory cell of the EEPROM 7 has the data Mdataij stored on an upper-order bit side for instance of the memory address Addrij as a set with the error detecting code EDC (Mdij−1) corresponding to data Mdataij−1 shifted by one memory address stored on a lower-order bit side.

To be more specific, the memory cell of each memory address Addrij has a data set {Mdataij, EDC (Mdij−1)} stored therein.

And in the case where a data readout instruction is given to the semiconductor storage device 11 via the CPU 3, the error check circuit 8 verifies the data and the error detecting code corresponding to the data as mentioned above. As for each of the error detecting codes, a parity symbol, a CRC symbol or the like is widely used. Without such limitation, however, an arbitrary symbol or the like capable of detecting the error of the data may be utilized.

In the case where two EEPROMs 7a and 7b which are physically different are prepared as the EEPROM 7 as the memory, the two EEPROMs are similarly applicable by reading the memory cell on the upper-order bit side as the memory cell of the EEPROM 7a for instance where the data is stored and reading the memory cell on the lower-order bit side as the memory cell of the EEPROM 7b where the error detecting code corresponding to the data is stored respectively.

Next, the operation of the IC card chip 1 on which the semiconductor storage device 11 according to the present embodiment is provided will be described.

As mentioned above, a description will be given as to the state where the EEPROM 7 of the semiconductor storage device 11 has the data and the error detecting code corresponding to the data stored and held at different memory addresses.

In this case, the information on the memory addresses in the EEPROM 7 at which the data and the error detecting code are held is included in the data/error detecting code storage address control circuit 13 in the error check circuit 8 for instance.

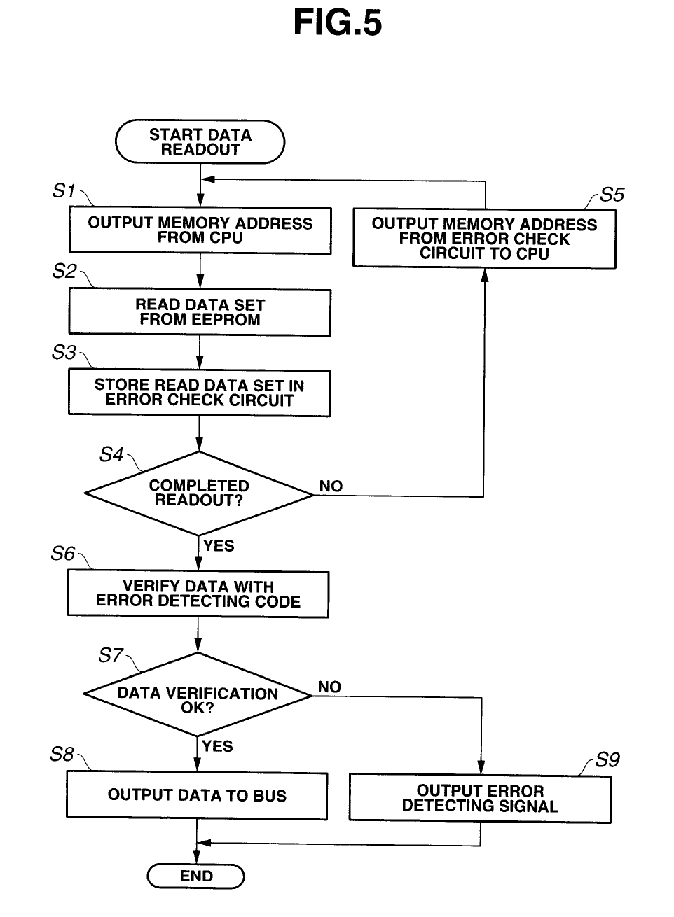

FIG. 5 shows a flowchart of an operational procedure on reading (reading out) the data from the semiconductor storage device 11 according to the present embodiment.

The entire operation will be described based on FIG. 5. In that case, a description will be given by using concrete examples of FIGS. 3 and 4.

If a data readout operation is started by a data readout instruction, the memory addresses on data readout are outputted from the CPU 3 as shown in step S1.

The memory addresses are also inputted to the data/error detecting code storage address control circuit 13 in the error check circuit 8. The data/error detecting code storage address control circuit 13 transmits a readout request signal to the CPU 3 on data readout.

As shown in step S2, the memory addresses from the CPU 3 are inputted to the address decoder 12 of the EEPROM 7. The data set is read out from the memory cell of the corresponding memory address from the EEPROM 7 via the address decoder 12.

As shown in step S3, the read data set is transmitted to the error check circuit 8, and is stored in a register or the like in the error check circuit 8.

The example of FIG. 3 indicates the memory address Addr on data readout as 01 in decimal representation. The example of FIG. 3 also indicates the memory address Addr as [001] in binary representation. Hereafter, [ ] is used for the binary representation. As shown in FIG. 3 and the like, in the case of putting down the memory address Addr in both the decimal and binary representations, the memory address is described as Addr01: [001].

And the memory address Addr01: [001] is outputted from the CPU 3 to the address decoder 12 of the EEPROM 7. A corresponding data set {Mdata01, EDC (Md00)} is read out from the EEPROM 7 and stored in the error check circuit 8.

If the read data set {Mdata01, EDC (Md00)} is stored in the error check circuit 8, the data/error detecting code storage address control circuit 13 in the error check circuit 8 outputs a readout end flag signal (on data readout) to the CPU 3.

As shown in FIG. 4, after outputting the readout end flag signal to the CPU 3, the data/error detecting code storage address control circuit 13 outputs to the CPU 3 a memory address Addr02: [010] for the sake of reading out an error detecting code corresponding to the data Mdata01. The data/error detecting code storage address control circuit 13 also outputs the readout request signal to the CPU 3.

In FIG. 5, in step S4 following step S3, the CPU 3 determines that the readout is yet to be completed based on the readout request signal from the data/error detecting code storage address control circuit 13, and moves on to the process of step S5 and then returns to the process of step S1.

In the concrete example shown in FIG. 4, the memory address Addr on data readout is 01[001]. The data/error detecting code storage address control circuit 13 outputs to the CPU 3 (the value of) the memory address Addr02 [010] as address information for the sake of reading out the error detecting code corresponding to the memory address.

If the memory address Addr02 [010] is inputted, the CPU 3 outputs the memory address Addr02 [010] to the address decoder 12 of the EEPROM 7 (step S2 of FIG. 5) as in the case of the data readout.

And as shown in FIG. 4, a data set {Mdata02, EDC (Md01)} made up of the data Mdata02 and the error detecting code EDC (Md01) stored at the memory address Addr02 [010] of the EEPROM 7 is read out (step S3 of FIG. 5).

And as shown in FIG. 4, the data set {Mdata02, EDC (Md01)} read out is stored in the register or the like in the error check circuit 8 (step S3 of FIG. 5).

If the data set {Mdata02, EDC (Md01)} on error detecting code readout is stored in the register or the like of the error check circuit 8, the data/error detecting code storage address control circuit 13 transmits the readout end flag signal to the CPU 3.

Thus, in the process of step S4 following step S3 of FIG. 5, the CPU 3 or the error check circuit 8 determines that the readout has been completed, and moves on to the process of verifying the data and the error detecting code in step S6. The process of step S6 is performed by the error check circuit 8.

And the error check circuit 8 determines whether or not the verification is OK, that is, whether or not there is an error in the data according to the verification result as indicated in step S7. In the case where it is determined that there is no error in the data by the determination, the error check circuit 8 outputs the data to the bus 10 as shown in step S8.

In the case where it is determined that there is an error, as shown in step S8, the error check circuit 8 does not output the data to the bus 10 but outputs the error detecting signal to the bus 10 and the like.

In the concrete example shown in FIG. 4, according to the step S6, the error check circuit 8 verifies the data Mdata01 on the upper-order bit side for instance stored for the first time (data readout) with the error detecting code EDC (Md01) on the lower-order bit side for instance stored for the second time (on error detecting code readout).

And the error check circuit 8 determines whether or not the verification result is OK as shown in step S7 of FIG. 5.

The example shown in FIG. 4 shows the case of verifying the data Mdata01 of the first time and the error detecting code EDC (Md01) of the second time. Therefore, in this case, the error check circuit 8 determines that there is no error and outputs the data Mdata01 to the bus 10 as shown in step S8 of FIG. 5. In the case of determining that there is an error as a result of the verification, the error check circuit 8 outputs the error detecting signal as shown in step S9.

FIGS. 3 and 4 described the case of normally reading out the data from the EEPROM 7.

According to the present embodiment, as mentioned above, the data and the error detecting code corresponding to the data are stored at the different memory addresses shifted by one in the EEPROM 7 as the memory.

And when reading out the data, it is possible to verify whether or not there is an error by reading out the data held in the EEPROM 7 and the error detecting code stored at a different memory address respectively and then verifying the data and the error detecting code.

For that reason, even in the case where an attacker attacks the address decoder 12 and tampers with the memory addresses in order to attempt failure-based analysis of an encryption key, the tampering is detectable as an error. In the case where the attacker attacks the data in order to attempt the failure-based analysis of the encryption key, the error is detectable as in the conventional cases and so a description thereof will be omitted.

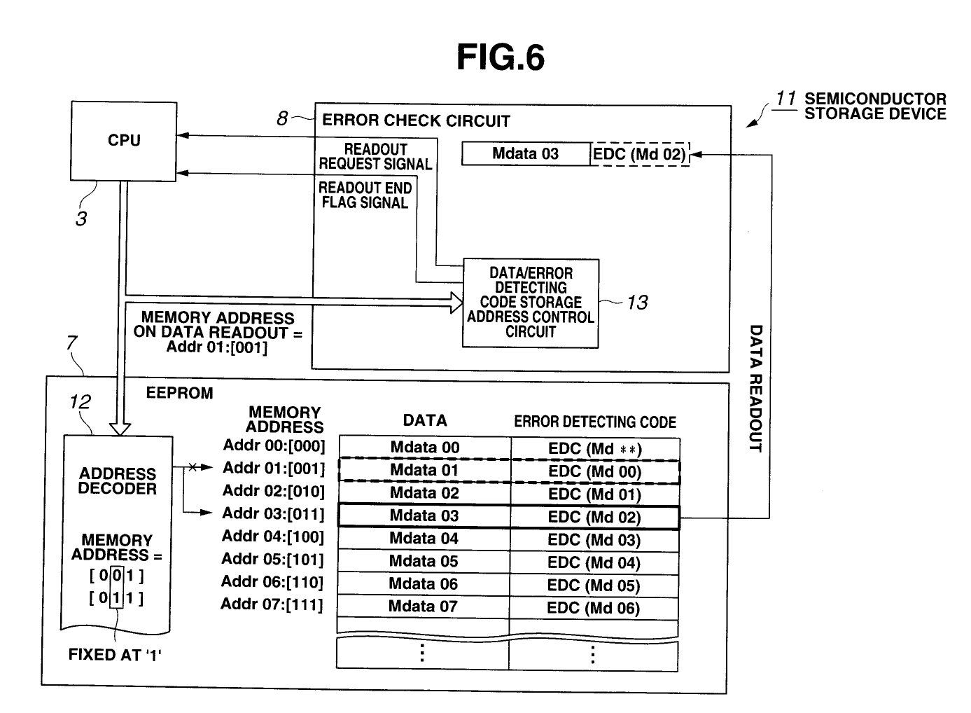

Hereafter, the operation in the case of tampering with the memory addresses will be described by using FIG. 6. A description will be given as to an example wherein, due to the attack on the address decoder 12 by the attacker, a second bit for instance of an original memory address Addr01 [001] of the memory address Addr is fixed at ‘1.’

Even in this case, the process is performed at first according to the processing from step S1 of the flowchart shown in FIG. 5. In this case, the memory address Addr outputted from the CPU 3 in step S1 is the memory address Addr01 [001].

And the memory address Addr01 [001] is inputted to the data/error detecting code storage address control circuit 13 of the error check circuit 8.

The memory address Addr01 [001] is also outputted to the address decoder 12 of the EEPROM 7. As shown in FIG. 6, however, the memory address becomes Addr03 [011] because the second bit is fixed at ‘1.’

And a data set {Mdata03, EDC (Md02)} of the memory address Addr03 [011] is read out from the EEPROM 7 and stored in the error check circuit 8.

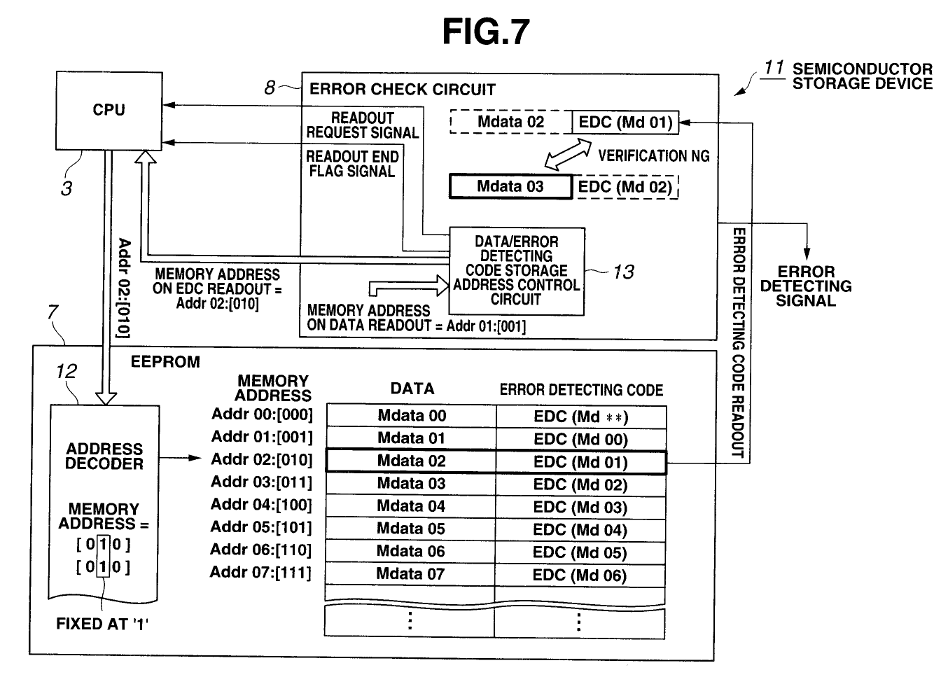

As above, the memory address Addr01 [001] is inputted to the data/error detecting code storage address control circuit 13. And as shown in FIG. 7, the memory address Addr02 [010] on error detecting code readout is outputted to the CPU 3 from the data/error detecting code storage address control circuit 13.

As for the second time, the second bit of the address decoder 12 is fixed at ‘1.’ Therefore, the corresponding data set {Mdata02, EDC (Md01)} is read out from the memory address Addr02 [010] of the EEPROM 7, and the data set {Mdata02, EDC (Md01)} is stored in the error check circuit 8.

In this case, the error check circuit 8 checks whether or not there is an error as to the first-time data Mdata03 and second-time error detecting code EDC (Md01). And in this case, the error check circuit 8 determines that there is an error and outputs the error detecting signal.

According to the present embodiment thus operating, the error is detected and the error detecting signal is outputted by the error check circuit 8 so that tampering with the memory addresses by the attacker is also detectable.

Other than the situation where the memory addresses are artificially changed such as the case where the memory addresses are tampered with by the attacker, it is also possible to detect the error by the same operation in the case where an error simply occurs to the memory addresses during operation of the IC and the memory addresses are changed so that wrong data is read.

Consequently, it is possible to improve reliability of the memory and resistance against the attack on the IC card such as the failure-based analysis.

As mentioned above, as a characteristic of the present embodiment, the error detecting code is held at a different memory address from the corresponding data, which is not limited to what is shown in FIG. 3. Examples of storage forms of the present embodiment which are different from the case of FIG. 3 will be concretely described by the following (1) to (5).

(1) Form of storing the error detecting codes by shifting the memory addresses against placement of the corresponding data

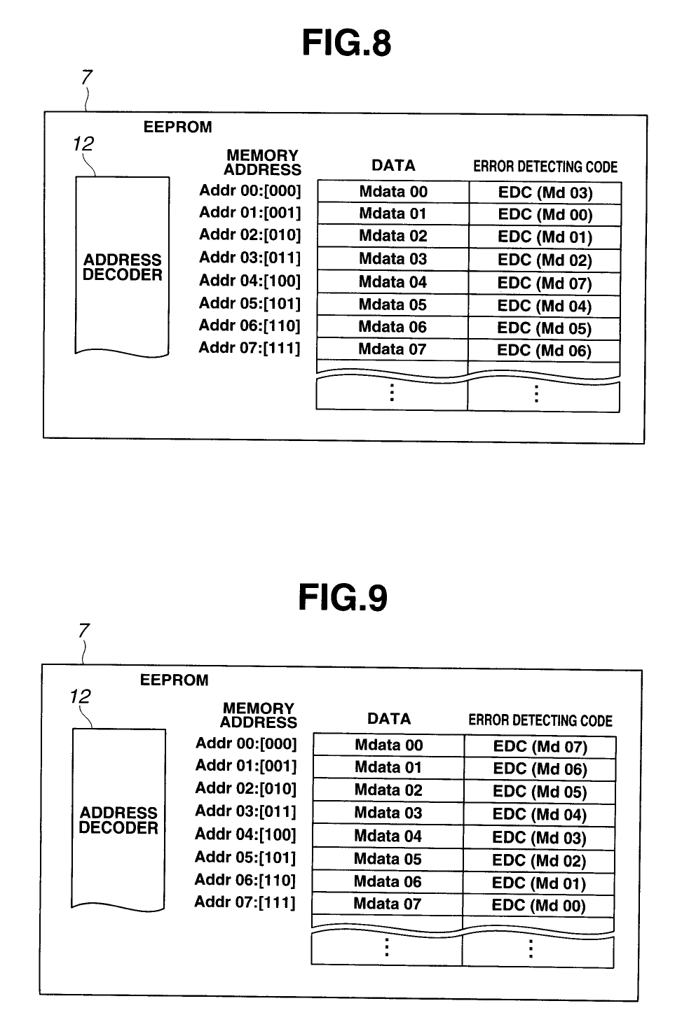

An example of the form of (1) is shown in FIG. 8. Like the case of FIG. 3, FIG. 8 is the form in which the memory addresses storing the error detecting codes are stored in positions shifted on the whole against positions of the memory addresses of the data.

In the example of FIG. 8, the data set is formed with four memory addresses as one set (period) for instance as a difference from FIG. 3. In this case, Mdata00 to Mdata03 and EDC (Md03), EDC (Md00) to EDC (Md02) are stored and held at the memory addresses [001] to [011] respectively. And Mdata04 to Mdata07 and EDC (Md07), EDC (Md04) to EDC (Md06) are stored and held at the memory addresses [100] to [111] respectively.

(2) Form of storing the error detecting codes in the memory in inverse order to the placement of the corresponding data

An example of the form of (2) is shown in FIG. 9. The data Mdata00 to Mdata07 is stored and held in ascending order in the memory cells of the respective memory addresses [000] to [111].

As for the error detecting code corresponding to each of the data, EDC (Md07) is stored in the memory cell of the memory address [000] and EDC (Md06) is stored at the memory address [001]. Thus, in the form, the error detecting codes are stored in inverse order to the placement of the corresponding data.

In this case, if the memory address of the data Mdata is ij, the memory address of the corresponding error detecting code is 7-(i+j), where the other address value changes depending on one address value in their memory address relation.

To be more specific, the memory address values do not shift one by one (or by one constant) on the whole as shown in FIG. 3. Instead, the memory address relation is set up so that the other corresponding memory address value changes according to one memory address value. Thus, the function of data protection can be further improved.

(3) Form of mutually interchanging the error detecting codes and thereby storing them at different memory addresses from the placement of the corresponding data

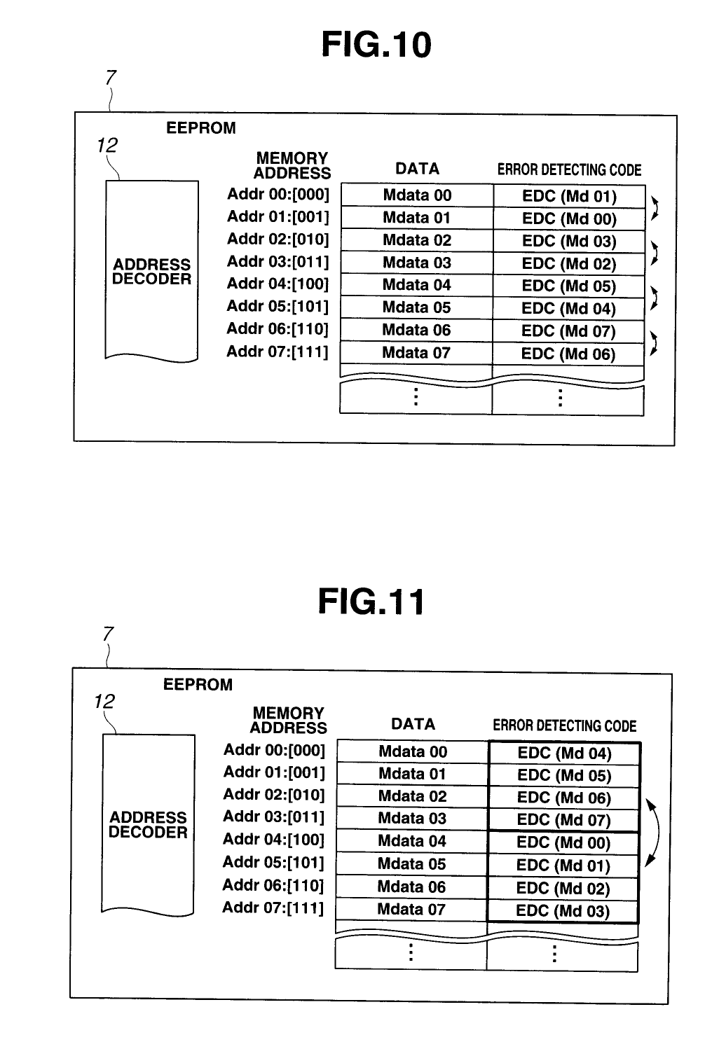

A first example according to the form of (3) is shown in FIG. 10. The example of FIG. 10 is in the form in which the error detecting codes and the corresponding data are stored at the same memory addresses, and then the error detecting codes stored at odd-numbered memory addresses are mutually interchanged with the error detecting codes stored at even-numbered memory addresses so as to be stored.

In the case of the form in which the error detecting codes are thus mutually interchanged, it is also possible to follow the second example shown in FIG. 11 other than mutually interchanging each individual error detecting code as in the example shown in FIG. 10.

The example of FIG. 11 is the form in which the error detecting codes are rendered as certain orderly sets (divided into two sets according to the parts of the data Md00 to Md03 and Md04 to Md07 in the case of this example) and the error detecting codes of the respective sets are mutually interchanged so as to store them at different memory addresses from the corresponding data placement.

To be more precise, EDC (Md04) to EDC (Md07) are stored in the memory cells of the memory addresses [001] to [011], and EDC (Md00) to EDC (Md03) are stored in the memory cells of the memory addresses [100] to [111] respectively.

(4) Form of dividing the data (Mdata) into the upper-order bit side and the lower-order bit side and storing one of the divided data at different memory addresses

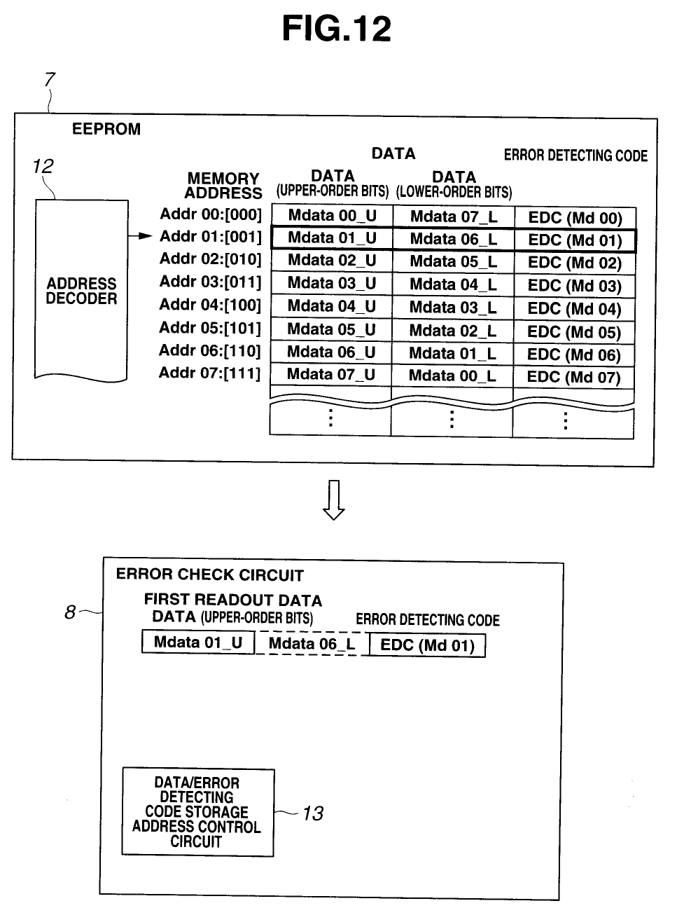

An example of the form of (4) is shown in FIG. 12. FIG. 12 is the form in which the error detecting codes and the corresponding data are stored at the same memory addresses and then each of the data Mdata00 to Mdata07 is divided into an upper-order bit: Mdata_U and a lower-order bit: Mdata_L respectively.

And the data of the upper-order bit or the lower-order bit is stored at different memory addresses from the error detecting codes EDC (Md00) to EDC (Md07).

In the concrete example of FIG. 12, the upper-order bit data Mdata00_U to Mdata07_U is stored in the memory cells of the same memory addresses as the error detecting codes EDC (Md00) to EDC (Md07). The lower-order bit data is placed like Mdata07_L to Mdata00_L in the memory cells of the memory addresses [100] to [111] for instance so as to be stored at different memory addresses from the error detecting codes EDC (Md00) to EDC (Md07).

And the memory address-related information is stored in the data/error detecting code storage address control circuit 13.

The operation from the data set readout to the verification by the error check circuit 8 is basically the same as the aforementioned operational description, where the data and the like are read out by accessing the EEPROM 7 as the memory twice.

Upon the first readout, the upper-order bit data Mdata01_U and the error detecting code EDC (Md01) of the memory address Addr01 [001] for instance are read out from the EEPROM 7 as the memory and stored in the error check circuit 8 as shown on the downside of FIG. 12.

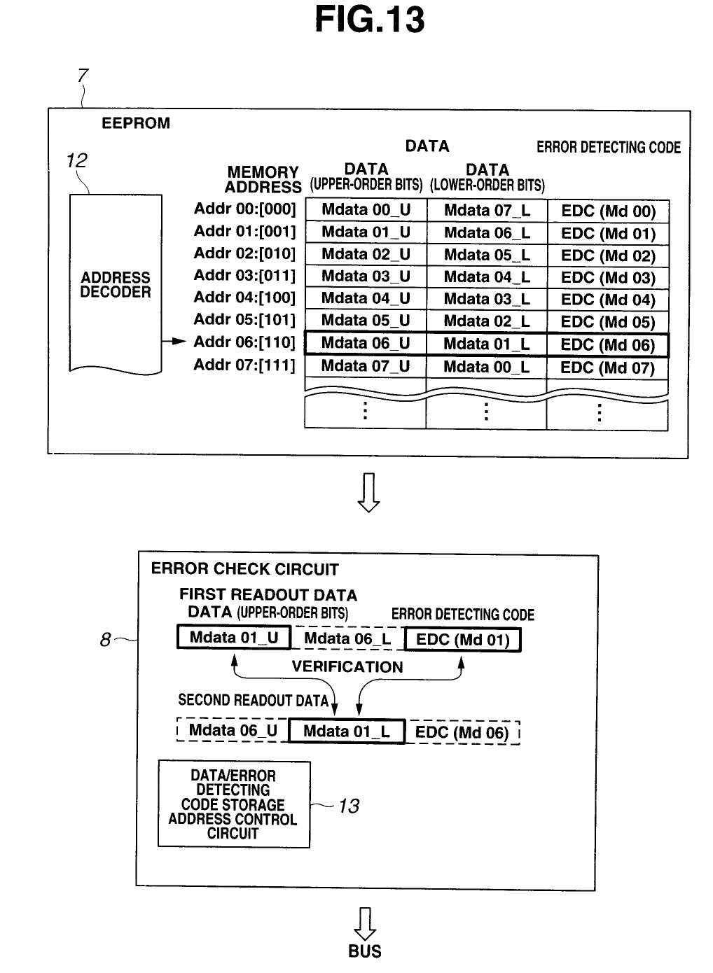

Upon the second readout, the lower-order bit data Mdata01_L of the memory address Addr06 [110] is read out from the EEPROM 7 and stored in the error check circuit 8 as shown in FIG. 13. Moreover, the first to second readouts are performed by means of the memory address-related information stored in the data/error detecting code storage address control circuit 13.

The error check circuit 8 checks whether or not there is an error by performing the verification using the data Mdata01_U and the error detecting code EDC (Md01) read out on the first readout and the data Mdata01_L of the second readout. In the case of FIG. 13, the data is outputted to the bus as no error.

The readouts of FIGS. 12 and 13 show the examples where only the information necessary to the error check is stored in the error check circuit 8. As shown in FIGS. 3, 4 and the like, however, it is also possible to read out each of the data as the data set and extract the necessary data and error detecting codes on the error check circuit 8 side so as to perform the verification of the error check.

(5) Form including an area which stores only the data and an area which stores only the error detecting codes in the memory cell

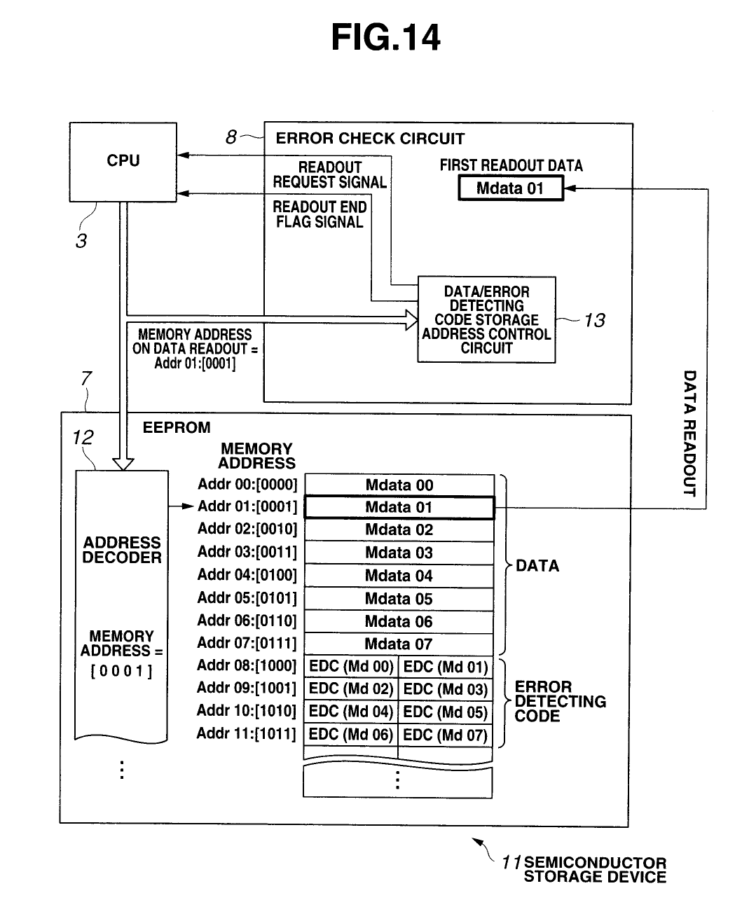

An example of the form of (5) is shown in FIG. 14. The storage form is not the form in which the data and error detecting code such as {Mdata00, EDC (Md00)} are stored in the memory cell of one memory address but is the form in which only the data or only the error detecting code is stored in the memory cell of one memory address.

In other words, the form is configured to store the data in the first memory specified by the first memory address and store the error detecting code corresponding to the data in the second memory specified by the second memory address which is set up in a predetermined relation with the first memory address and different from the first memory address.

In the concrete example of FIG. 14, the data Mdata00 to Mdata07 is stored in the respective memory cells of the memory addresses of Addr00 [0000] to Addr07 [0111], and the error detecting codes EDC (Md00) to EDC (Md07) are stored in the respective memory cells of the memory addresses of Addr08: [1000] to Addr11: [1011] by a set of two (EDC (Md00) and EDC (Md01) at Addr08 [1000] for instance).

The operation from the readout to the verification by the error check circuit 8 is basically the same as the aforementioned operational description, where the data and the like are read out by accessing the EEPROM 7 as the memory twice on readout.

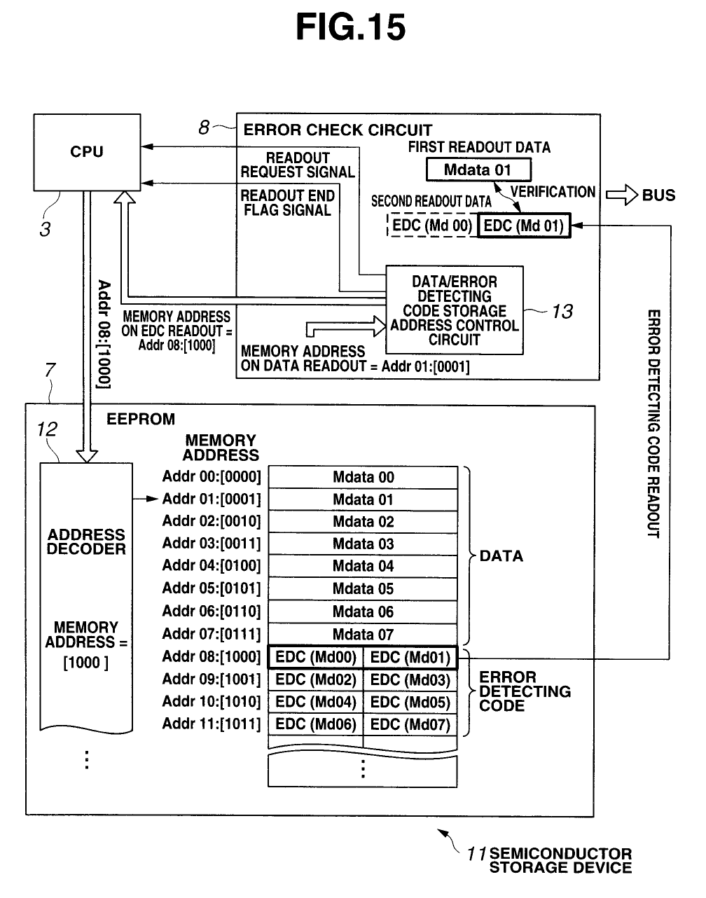

As shown in FIG. 14, the data Mdata01 is read out from the EEPROM 7 on the first data readout and is stored in the error check circuit 8. As shown in FIG. 15, the error detecting code EDC (Md01) is read out from the EEPROM 7 on the second error detecting code readout and stored in the error check circuit 8. And the error check circuit 8 verifies the first-time data Mdata01 with the error detecting code EDC (Md01).

In the configuration of this case, the error is also detectable in the case where the attacker attacks on the memory addresses or the error occurs to the memory addresses. Thus, the storage form examples of the data and the error detecting codes taken as (1), (2), (3), (4) and (5) have approximately the same advantages as the cases described in FIGS. 3 and 4.

Any storage form other than those taken as (1), (2), (3), (4) and (5) has the same advantages as the present embodiment and belongs to the category of the present invention if the form satisfies the characteristic of storing the error detecting codes at different memory addresses from the corresponding data.

As mentioned above, according to the present embodiment, the data stored in the memory can be protected with a simple configuration. To be more precise, the error is detectable in the case where the error occurs not only to the data of the memory but also to the memory addresses.

Consequently, it is possible to improve the resistance against the attack on a device such as the IC card with the memory mounted thereon of the failure-based analysis or the like, that is, effectively prevent leakage of information and improve reliability of the device.

The above described the case of reading twice as an example of reading out the data and the like from the memory multiple times. It is also possible, however, to have a configuration where the data and the like are read out three or more times so as to further secure confidentiality of the information.

For instance, as in FIG. 12, the data is divided into an upper-order bit: and a lower-order bit, and the data of the upper-order and lower-order bits are stored at different memory addresses from those storing the corresponding error detecting codes.

Thus, it becomes necessary to access the memory three times in order to read out the data and the error detecting codes from the memory three times. And only in the case where the information on a correct correspondence relation is read out at each of the three times, the data is outputted as no error. Thus, the leakage of the data to be protected can be more securely prevented.

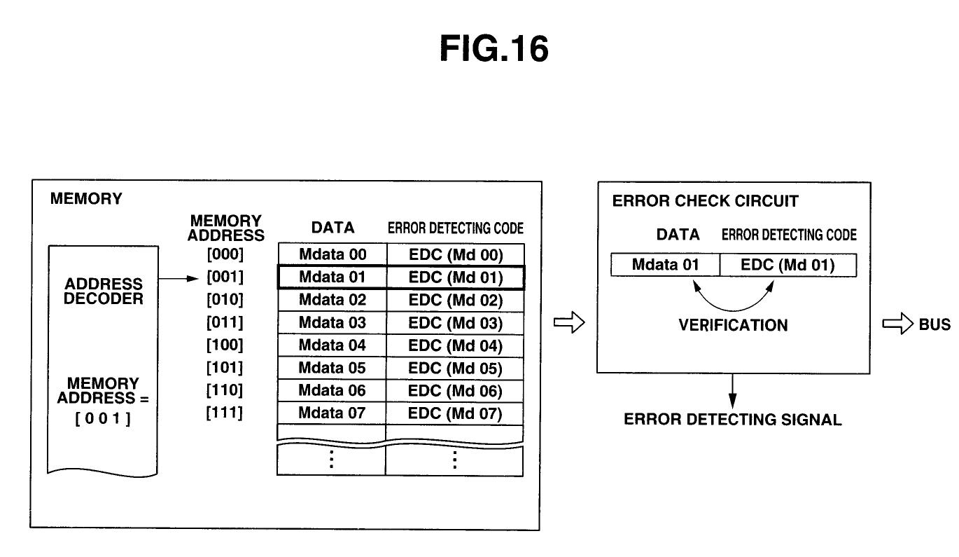

A comparison example in the case of using a heretofore known technology will be described in comparison with the above-mentioned embodiment. Hereafter, characteristics in the case of Japanese Patent Laid-Open No. 2003-51817 will be described. As shown in FIG. 16, Japanese Patent Laid-Open No. 2003-51817 adopts a structure in which the memory stores the data portion Mdata and the error detecting codes EDC (Md) corresponding to the data in the memory cells of the same memory addresses.

Bit width of each individual memory is a sum of the bits equivalent to 1 Word of Mdata and check bits of the corresponding Mdata corresponding to a hamming code (the bit width necessary to the check bits is decided by the bit width of 1 Word of Mdata. By way of example, the necessary check bits are 4 bits in the case where Mdata is 8 bits).

As for the technique, in the case of reading Mdata01 held at the memory address Addr [001] ([001] is binary representation here) for instance, the data set {Mdata01, EDC (Md01)} read out from the memory address [001] is captured by the error check circuit and is then checked whether or not there is an error in the read data.

In this case, the error check circuit checks the data and transmits the data as-is to the bus if there is no error. In the case where there is an error in the data, however, the error check circuit outputs the error detecting signal, thereby allowing the tampering with the memory contents by the attacker to be detected.

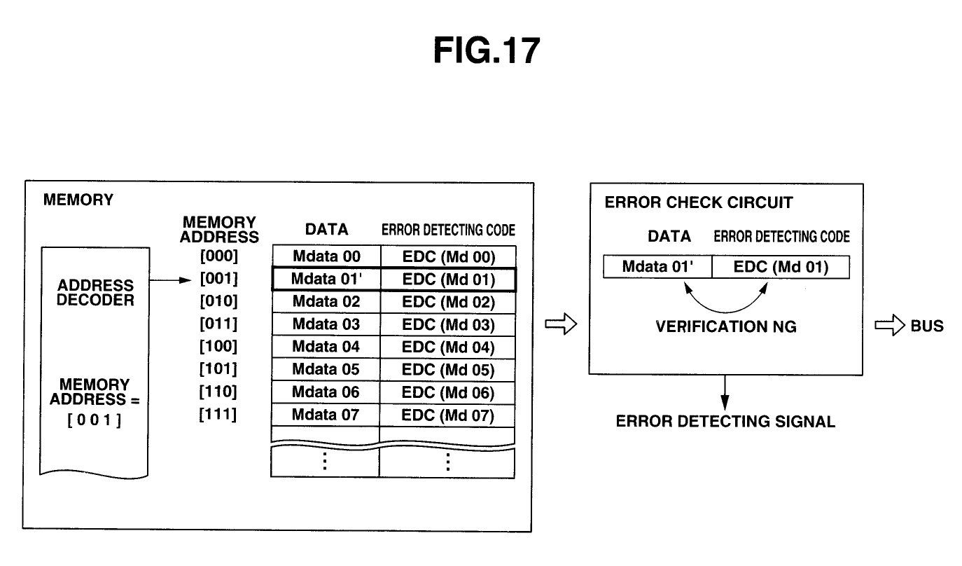

As shown in FIG. 17, the attacker has actually tampered with the data by changing a bit pattern of the data Mdata01 held at the memory address [001], and as a result, a change has been made from Mdata01 (before the tampering) to Mdata01′ (after the tampering).

If the data is read out from the memory address [001] in this state, the data set {Mdata01′, EDC (Md01)} is read out and transmitted to the error check circuit, and data verification is executed thereafter. Here, EDC (Md01) is the error detecting code corresponding to the data Mdata01 before the tampering. Therefore, the result of the verification with the data Mdata01′ which has been tampered with is naturally NG (there is an error).

Therefore, according to the method of Patent Document 1, the tampering with the data portion of the memory is detectable by the error check circuit as in FIG. 17.

However, the attack made by the attacker for the sake of attempting the failure-based analysis is not limited to directly tampering with the data of the data portion of the memory. There is also a method of changing the memory addresses and causing the memory address different from the correct memory address to be accessed, thereby causing incorrect data to be read out.

As for the attack method of attacking the address decoder, reading out the improper data and putting the IC in a failed state, there is a problem that the attack is not detectable by the method of Patent Document 1.

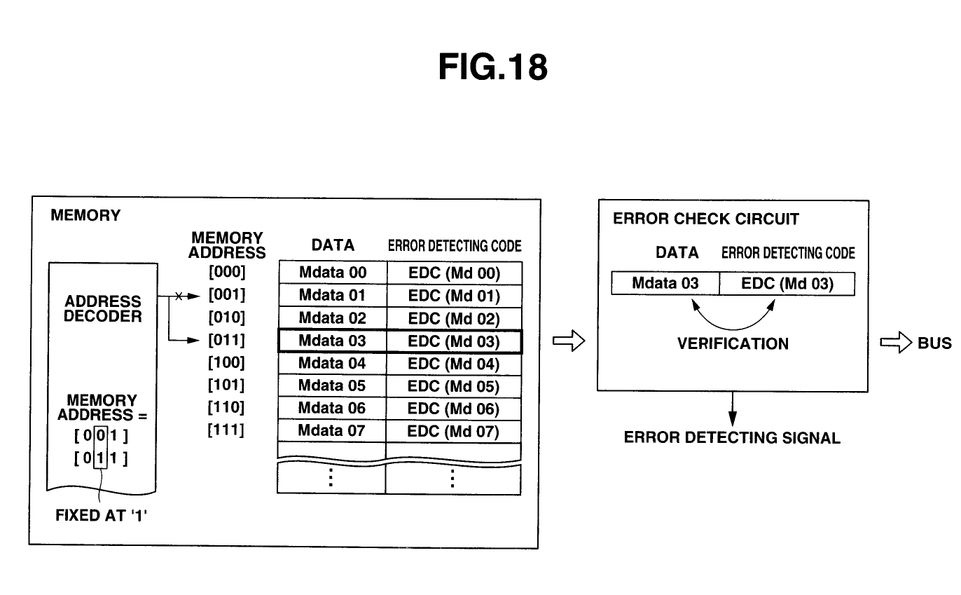

As an example thereof, thought is given to the case where an attack on the address decoder is made by the attacker when reading Mdata01 held at the memory address [001] as shown in FIG. 18.

To read Mdata01, the memory address [001] is specified. However, in the case where the highest-order bit of the memory address is fixed at ‘1’ by the attacker for instance, the value of the memory address changes from [001] (before the tampering) to [101] (after the tampering).

And the data set {Mdata05, EDC (Md05)} of the address [101] actually tampered with is read from the memory instead of the data set {Mdata01, EDC (Md01)} of the memory address [001] which should originally be read out.

The data set {Mdata05, EDC (Md05)} read out in this case is captured by the error check circuit and is then checked whether or not there is an error. However, the data itself has not been tampered with, and ‘EDC (Md05)’ is also a correct error detecting code corresponding to the read data ‘Mdata05.’

For that reason, the verification result of the data set {Mdata05, EDC (Md05)} by the error check circuit becomes “no error” so that the error detecting signal is not outputted.

In comparison, the above-mentioned present embodiment can detect the error in the case where the system reads the unexpected improper data.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor storage device comprising:
a memory configured to store data at a first address and store an error detecting code corresponding to the data at a second address which is set up in a predetermined relation with the first address and different from the first address; and
an address storage portion configured to store information on address relation between the first address and the second address.

2. The semiconductor storage device according to claim 1, further comprising:
an error check portion configured to read out the data and the error detecting code and perform an error check of the data.

3. The semiconductor storage device according to claim 1, wherein:
the data and the error detecting code corresponding to data different from the data are stored as a data set in a memory cell of the memory specified by the first address.

4. The semiconductor storage device according to claim 2, wherein:
the data and the error detecting code corresponding to data different from the data are stored as a data set in a memory cell of the memory specified by the first address.

5. The semiconductor storage device according to claim 1, wherein:
the address relation between the first address and the second address is set up as relation in which a value of one address changes depending on the value of the other address.

6. The semiconductor storage device according to claim 2, wherein:
the address relation between the first address and the second address is set up as relation in which a value of one address changes depending on the value of the other address.

7. The semiconductor storage device according to claim 1, wherein:
the data and the error detecting code corresponding to data are read out from the memory multiple times.

8. The semiconductor storage device according to claim 2, wherein:
the data and the error detecting code corresponding to data are read out from the memory multiple times.

9. A semiconductor storage device comprising:
a memory configured to store combination data having mutually different first data and second data divided at a first address and store an error detecting code corresponding to the first or second data at a second address which is set up in a predetermined relation with the first address and different from the first address; and
an address storage portion configured to store information on address relation between the first address and the second address.

10. The semiconductor storage device according to claim 9, further comprising:
an error check portion configured to read out the data and the error detecting code, and perform an error check of the data.

11. The semiconductor storage device according to claim 9, wherein:
the data includes two divided data, that is, the divided data including an upper-order side bit of the first data and the divided data including a lower-order side bit of the second data in the case of dividing each of the first data and the second data into two.

12. The semiconductor storage device according to claim 10, wherein:
the data includes two divided data, that is, the divided data including an upper-order side bit of the first data and the divided data including a lower-order side bit of the second data in the case of dividing each of the first data and the second data into two.

13. A semiconductor storage device comprising:
a first memory configured to store data at a first address;
a second memory configured to store an error detecting code corresponding to the data at a second address which is set up in a predetermined relation with the first address and different from the first address; and
an address storage portion configured to store information on address relation between the first address and the second address.

14. The semiconductor storage device according to claim 13, further comprising:
an error check portion configured to read out the data and the error detecting code and perform an error check of the data.

15. The semiconductor storage device according to claim 13, comprising:
the memories including the first memory and the second memory, wherein:
the data and the error detecting code corresponding to data different from the data are stored as a data set in a memory cell of the memories specified by the first address.

16. The semiconductor storage device according to claim 14, comprising:
the memories including the first memory and the second memory, wherein:
the data and the error detecting code corresponding to data different from the data are stored as a data set in a memory cell of the memory specified by the first address.

17. The semiconductor storage device according to claim 13, wherein:
the address relation between the first address and the second address is set up as relation in which a value of one address changes depending on the value of the other address.

18. The semiconductor storage device according to claim 14, wherein:
the address relation between the first address and the second address is set up as relation in which a value of one address changes depending on the value of the other address.

19. The semiconductor storage device according to claim 13, wherein:
the data and the error detecting code corresponding to data are read out from the first memory and the second memory multiple times.

20. The semiconductor storage device according to claim 14, wherein:
the data and the error detecting code corresponding to data are read out from the first memory and the second memory multiple times.
